(19) United States
(12) Patent Application Publication
(10) Pub. No.: US 2012/0170671 A1
(43) Pub. Date: Jul. 5, 2012

(54) INTEGRATED CIRCUIT CHIP, SYSTEM INCLUDING MASTER CHIP AND SLAVE CHIP, AND OPERATION METHOD THEREOF

(76) Inventor: Seung-Min OH, Gyeonggi-do (KR)

(21) Appl. No.: 13/334,034

(22) Filed: Dec. 21, 2011

(30) Foreign Application Priority Data
Dec. 30, 2010 (KR) 10-2010-0138535

(51) Int. Cl. H04L 27/00; G11C 7/10

(52) U.S. Cl. 375/259; 365/189.05

(57) ABSTRACT

An integrated circuit chip includes: a plurality of input pads; a plurality of first buffers respectively coupled with the input pads; and a plurality of second buffers respectively coupled with the input pads, wherein the first buffers are configured to receive signals of a higher frequency than the second buffer, wherein the second buffers and the first buffers are configured to selectively output the signals input to the selected buffers according to an operation mode that is set in response to an input signal.

### CROSS-REFERENCE TO RELATED APPLICATIONS

The present application claims priority of Korean Patent Application No. 10-2010-0138535, filed on Dec. 30, 2010, which is incorporated herein by reference in its entirety.

### BACKGROUND

1. Field

Exemplary embodiments of the present invention relate to a technology for controlling a buffer that receives input signals in an integrated circuit chip whose operation speed varies.

2. Description of the Related Art

Many integrated circuit chips vary in operation speed according to the application of the integrated circuit chips. Although an integrated circuit chip may operate at approximately 500 MHz, the integrated circuit chip may operate at approximately 100 MHz or at approximately 500 MHz according the type of system.

When the integrated circuit chip receives input signals in the same way when the integrated circuit chip operates at approximately 100 MHz and when the integrated circuit chip operates at approximately 500 MHz, the integrated circuit chip may have a decrease in performance and an increase in current consumption.

### SUMMARY

An embodiment of the present invention is directed to receiving input signals in a method appropriate for the operation speed of an integrated circuit chip to secure stable operation and reduce current consumption.

In accordance with an embodiment of the present invention, an integrated circuit chip includes: a plurality of input pads; a plurality of first buffers respectively coupled with the input pads; and a plurality of second buffers respectively coupled with the input pads, wherein the first buffers are configured to receive signals of a higher frequency than the second buffer, wherein the second buffers and the first buffers are configured to selectively output the signals input to the selected buffers according to an operation mode that is set in response to an input signal.

In accordance with another embodiment of the present invention, a system, comprising: master chip; a slave chip comprising a plurality of first buffers and a plurality of second buffers, wherein the plurality of first buffers are configured to receive signals of a higher frequency than the plurality of second buffers; and a plurality of lines configured to transfer signals between the master chip and the salve chip, wherein the master chip is configured to set an operation mode of the slave chip, and the slave chip is configured to select one group between the plurality of first buffers and the plurality of second buffers and receive the signals of the lines by using the selected buffers according to the set operation mode.

In accordance with yet another embodiment of the present invention, a method for operating a system including a master chip and a slave chip includes: setting an operation mode of the slave chip by the master chip; outputting a signal input to selected buffers that are selected between a plurality of first buffers and a plurality of second buffers in the slave chip in response to the operation mode; transferring a plurality of signals from the master chip to the slave chip; and receiving the signals in the slave chip by using the buffers selected in response to the operation mode, wherein the plurality of first buffers receive signals of a higher frequency than the plurality of second buffers

### BRIEF DESCRIPTION OF THE DRAWINGS

FIG. 1 illustrates an integrated circuit chip in accordance with an embodiment of the present invention.

FIG. 2 is a block view illustrating a system including a master chip and a slave chip in accordance with an embodiment of the present invention.

FIG. 3 is a flowchart illustrating an operation of the system shown in FIG. 2.

FIG. 4A is a circuit diagram illustrating an inverter-type buffer as an example of a low-speed buffer 120 shown in FIG. 1.

FIG. 4B is a circuit diagram illustrating an amplifier-type buffer as an example of a high-speed buffer 110 shown in FIG. 1.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

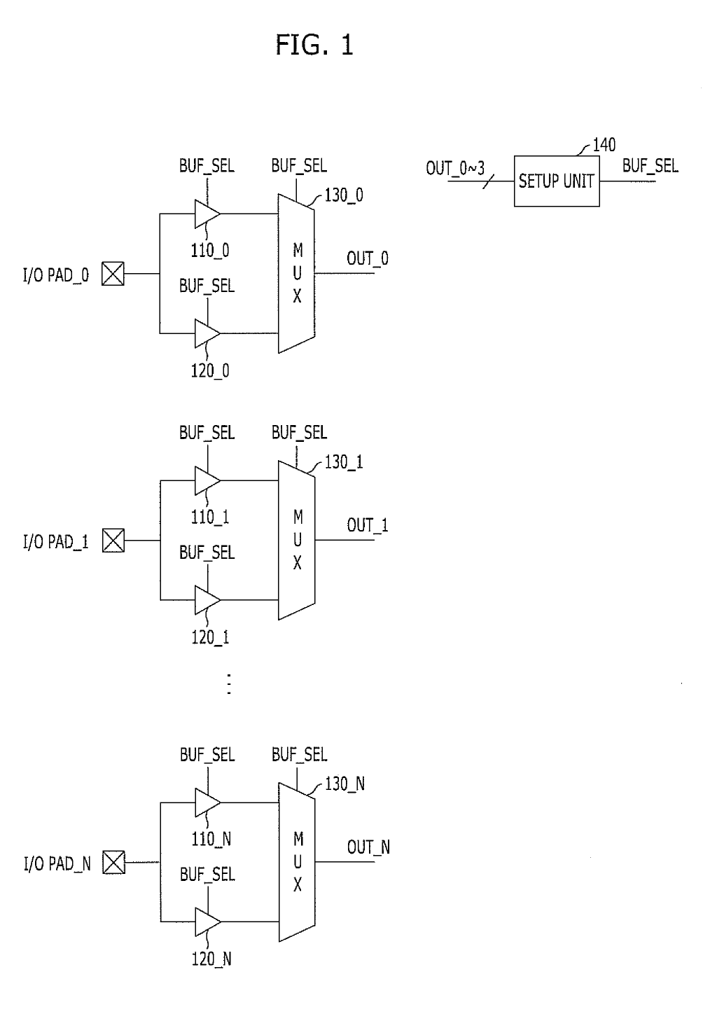

FIG. 1 illustrates an integrated circuit chip in accordance with an embodiment of the present invention.

Referring to FIG. 1, the integrated circuit chip includes a plurality of input pads I/O PAD_0 to N, a plurality of high-speed buffers 110_0 to N, a plurality of low-speed buffers 120_0 to N, a setup unit 140, and a plurality of selectors 130_0 to N.

The input pads I/O PAD_0 to N receive signals inputted from a circuit outside of the integrated circuit chip. The number of the input pads I/O PAD_0 to N is different according to the type of the integrated circuit chip. For example, when the integrated circuit chip is a memory device, the total number of input pads I/O PAD_0 to N may different according to the number of bits of a data channel and the number of bits of various control signals.

The high-speed buffers 110_0 to N may recognize both high-speed signals and low-speed signals that are inputted to the corresponding input pads I/O PAD_0 to N, but the high-speed buffers 110_0 to N may consume a large amount of current. The low-speed buffers 120_0 to N consume less current but do not recognize high-speed signals. The difference between the high-speed buffers 110_0 to N and the low-speed buffers 120_0 to N is relative. The high-speed buffers 110_0 to N are buffers that have relatively superior performance but consume much current, whereas the low-speed buffers 120_0 to N are buffers that consume relatively less current but have relatively inferior performance. Examples of the high-speed buffers 110_0 to N include an amplifier-type buffer, and examples of the low-speed buffers 120_0 to N include an inverter-type buffer. The high-speed buffers 110_0 to N are enabled when a buffer selection signal BUF_SEL is in a logic high level, and the low-speed buffers 120_0 to N is enabled when the buffer selection signal BUF_SEL is in a logic low level.

The setup unit 140 sets an operation mode based on a portion OUT_0 to 3 of input signals OUT_0 to N that are inputted through the input pads I/O PAD_0 to N. Of course, all of the input signals OUT_0 to N that are inputted through the input pads I/O PAD_0 to N may be used for setting the operation mode. The operation mode may be a high-speed operation mode or a low-speed operation mode. The operation mode may be set during the initial operation of the integrated circuit chip. When the operation mode is set as the high-speed operation mode based on a result of the setup unit 140 decoding the signals OUT_0 to 3, the buffer selection signal BUF_SEL is output at a logic high level. Therefore, when the high-speed operation mode is set, the high-speed buffers 110_0 to N are used to receive the signals of the input pads I/O PAD_0 to N. Also, when the operation mode is set as the low-speed operation mode based on a result of the setup unit 140 decoding the signals OUT_0 to 3, the buffer selection signal BUF_SEL is output at a logic low level. Therefore, when the low-speed operation mode is set, the low-speed buffers 120_0 to N are used to receive the signals of the input pads I/O PAD_0 to N.

The buffer selection signal BUF_SEL has an initial value before the setup unit 140 decodes the signals OUT_0 to 3. For example, the buffer selection signal BUF_SEL may have an initial value of a logic low level before the setup unit 140 sets the operation mode by decoding the signals OUT_0 to 3. The buffer selection signal BUF_SEL has an initial value because one type of buffers between the low-speed buffers 120_0 to N and the high-speed buffers 110_0 to N have to be enabled so that the setup unit 140 can decode an operation mode based on the signals OUT_0 to 3 inputted to the input pads I/O PAD_0 to 3.

The selectors 130_0 to N select and output the output of the high-speed buffers 110_0 to N while the high-speed buffers 110_0 to N are enabled, and the selectors 130_0 to N select and output the output of the low-speed buffers 120_0 to N while the low-speed buffers 120_0 to N are enabled. More specifically, the selectors 130_0 to N select the output of the high-speed buffers 110_0 to N when the buffer selection signal BUF_SEL is at a logic high level, and the selectors 130_0 to N select the output of the low-speed buffers 120_0 to N when the buffer selection signal BUF_SEL is at a logic low level. The output signals OUT_0 to N of the selectors 130_0 to N are transferred to an internal circuit of the integrated circuit chip.

According to an embodiment of the present invention, when the integrated circuit chip is set at the high-speed operation mode, the integrated circuit chip receives the signals that are applied to the input pads I/O PAD_0 to N using the high-speed buffers 110_0 to N. Therefore, the integrated circuit chip may accurately recognize the signals that are applied at a high speed during the high-speed operation mode. Also, when the integrated circuit chip is set at the low-speed operation mode, the integrated circuit chip receives the signals that are applied to the input pads I/O PAD_0 to N using the low-speed buffers 120_0 to N. Therefore, the integrated circuit chip may reduce the amount of current consumed when receiving the low speed signals.

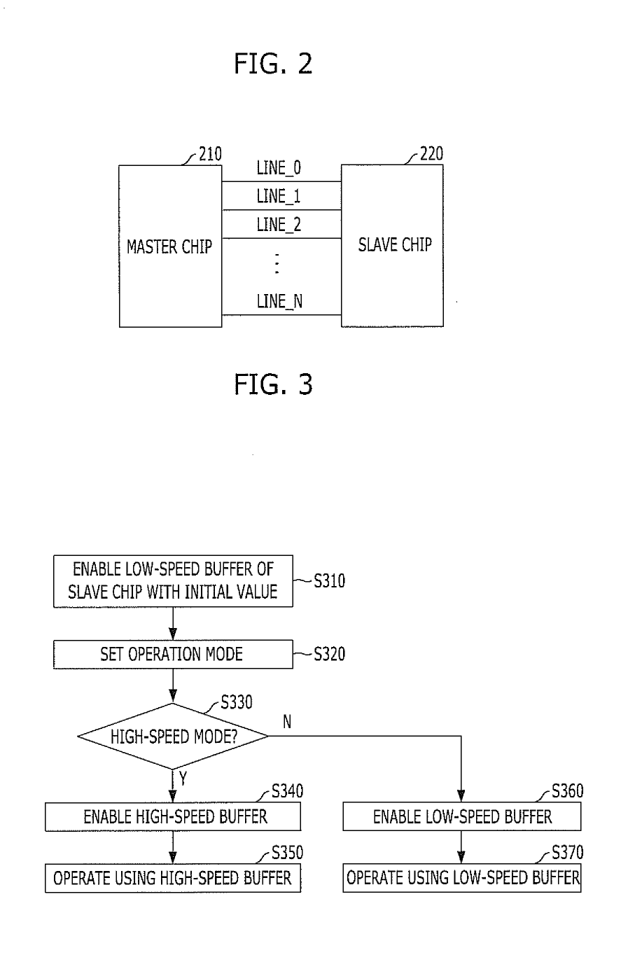

FIG. 2 is a block view illustrating a system including a master chip and a slave chip in accordance with an embodiment of the present invention.

Referring to FIG. 2, the system includes a master chip 210, a slave chip 220, and a plurality of lines LINE_0 to N.

The master chip 210 sets the operation mode of the slave chip 220 and controls the operation of the slave chip 220. The slave chip 220 operates under the control of the master chip 210. For example, the master chip 210 may be a memory controller chip and the slave chip 220 may be a memory chip. The integrated circuit chip shown in FIG. 1 corresponds to the slave chip 220 of FIG. 2.

The lines LINE_0 to N transfer data and control signals between the master chip 210 and the slave chip 220. As described with reference to FIG. 1, the slave chip 220 includes a plurality of high-speed buffers 110_0 to N and a plurality of low-speed buffers 120_0 to N that receive the signals of the lines LINE_0 to N. The type of buffers to be used in the inside of the slave chip 220 is decided based on whether the master chip 210 sets the operation mode of the slave chip 220 at the high-speed operation mode or at the low-speed operation mode. During the high-speed operation mode, signals are transferred at a high frequency through the lines LINE_0 to N, and during the low-speed operation mode, signals are transferred at a low frequency through the lines LINE_0 to N.

FIG. 3 is a flowchart describing an operation of the system shown in FIG. 2.

Referring to FIG. 3, the low-speed buffers 120_0 to N of the slave chip 220 are enabled based on the initial value L of the buffer selection signal BUF_SEL in step S310. If the initial value of the buffer selection signal BUF_SEL is set to a logic high level H, the high-speed buffers 110_0 to N would be enabled.

Information for setting the operation mode is inputted from the master chip 210 to the slave chip 220 through the lines LINE_0 to N, and the setup unit 140 inside the slave chip 220 sets the operation mode in step S320.

When the operation mode is set to the high-speed operation mode in step S330 (Y), the high-speed buffers 110_0 to N are enabled in step S340. The slave chip 220 subsequently receives the signal transferred from the master chip 210 through the enabled high-speed buffers 110_0 to N in step S350.

When the operation mode is set to the low-speed operation mode in step S330 (N), the low-speed buffers 120_0 to N are enabled in step S360. The slave chip 220 subsequently receives the signal transferred from the master chip 210 through the enabled low-speed buffers 120_0 to N in step S370.

As described above, the slave chip 220 in the system according to the embodiment of the present invention selects the type of the buffers to be used based on whether the slave chip 220 is set at the high-speed operation mode or the low-speed operation mode.

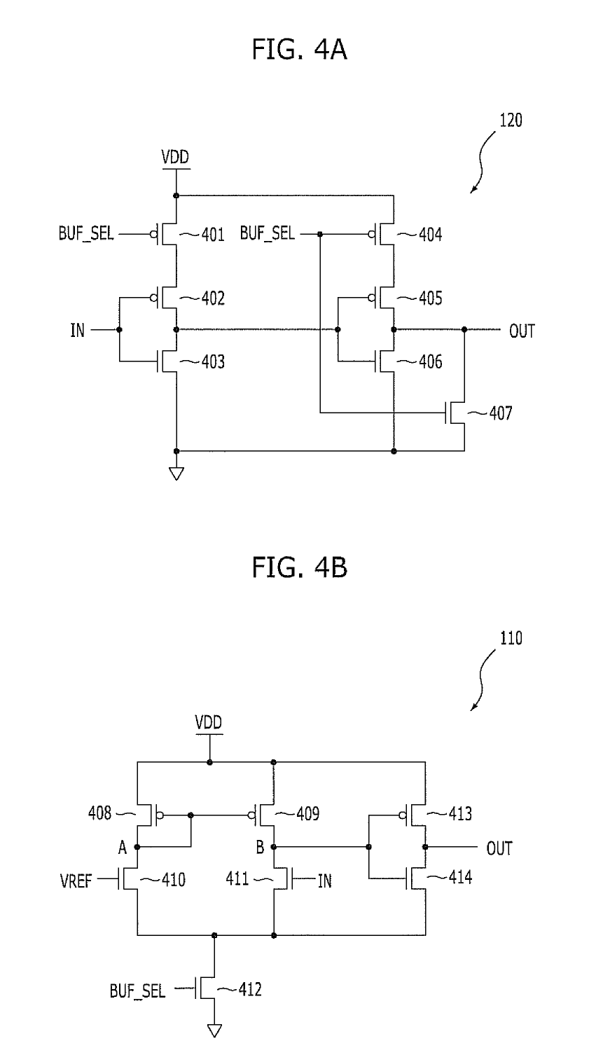

FIG. 4A is a circuit diagram illustrating an inverter-type buffer as an example of the low-speed buffer 120 shown in FIG. 1, and FIG. 4B is a circuit diagram illustrating an amplifier-type buffer as an example of the high-speed buffer 110 shown in FIG. 1.

Referring to FIG. 4A, the inverter-type buffer includes PMOS transistors 401, 402, 404 and 405 and NMOS transistors 403, 406 and 407.

When the buffer selection signal BUF_SEL is in a logic low level, the PMOS transistors 401 and 404 are turned on to enable the inverter-type buffer.

When an input signal IN has a high level while the inverter-type buffer is enabled, the NMOS transistor 403 and the PMOS transistor 405 are turned on, and thus the output signal OUT of the buffer is at a logic high level. When an input signal IN has a low level, the PMOS transistor 402 and the NMOS transistor 406 are turned on, and thus the output signal OUT of the buffer is in a logic low level. Since the inverter-type buffer consumes current only when a signal is inputted, it consumes a small amount of current. However, the inverter-type buffer cannot accurately recognize a signal inputted at a high speed, more specifically, the logic value of a signal having a narrow swing width. FIG. 4A illustrates a basic inverter-type buffer, and the inverter-type buffer may have a different structure from the structure of the inverter-type buffer shown in FIG. 4A.

Referring to FIG. 4B, the amplifier-type buffer has a structure of a differential amplifier that senses level difference between an input signal IN and a reference voltage VREF. Two PMOS transistors 408 and 409 constitute a current mirror structure to supply the same current to two nodes A and B, and the two nodes A and B are differentially amplified based on the level difference between the reference voltage VREF and the input signal IN that are respectively inputted to NMOS transistors 410 and 411. Based on the circuit configuration, when the input signal IN has a higher level than the reference voltage VREF, the output signal OUT has a logic high level, and when the input signal IN has a lower level than the reference voltage VREF, the output signal OUT has a logic low level. An NMOS transistor 412 that receives the buffer selection signal BUF_SEL is turned on when the buffer selection signal BUF_SEL is in a logic high level. When the NMOS transistor 412 is turned on, the buffer is enabled, and when the NMOS transistor 412 is turned off, the buffer is disabled. Based on the circuit configuration, the amplifier-type buffer is enabled when the buffer selection signal BUF_SEL is in a logic high level.

The amplifier-type buffer may accurately recognize the logic value of a signal even when the swing width of the input signal IN is narrow, more specifically, when the input signal IN is applied at a high speed/frequency, but the amplifier-type buffer consumes a large amount of current as the current flows through the amplifier-type buffer while the amplifier-type buffer is enabled. FIG. 4B illustrates a basic amplifier-type buffer, but the amplifier-type buffer may have diverse structures other than the structure shown in FIG. 4B.

According to the technology of the present invention, an efficient buffer is used according to the operation mode of an integrated circuit chip set by the setup unit. When the operation mode of an integrated circuit chip is set to a high-speed mode, the integrated circuit chip is designed to receive high speed input signals by using a high-speed buffer, and when the operation mode of an integrated circuit chip is set to a low-speed mode, the integrated circuit chip is designed to receive low speed input signals by using a low-speed buffer.

While the present invention has been described with respect to the specific embodiments, it will be apparent to those skilled in the art that various changes and modifications may be made without departing from the spirit and scope of the invention as defined in the following claims.

What is claimed is:

1. An integrated circuit chip, comprising:
a plurality of input pads;
a plurality of first buffers respectively coupled with the input pads; and
a plurality of second buffers respectively coupled with the input pads, wherein the first buffers are configured to receive signals of a higher frequency than the second buffer,
wherein the second buffers and the first buffers are configured to selectively output the signals input to the selected buffers according to an operation mode that is set in response to an input signal.

2. The integrated circuit chip of claim 1, wherein the integrated circuit chip is configured to be set in the operation mode during an initial operation of the integrated circuit chip.

3. The integrated circuit chip of claim 1, wherein one group between the plurality of first buffers and the plurality of second buffers selectively outputs the signal input to the selected buffers before the operation mode is set.

4. The integrated circuit chip of claim 3, further comprising:
a setup unit configured to set the operation mode in response to signals that are inputted through a portion of the plurality of buffers selected before the operation mode is set.

5. The integrated circuit chip of claim 3, further comprising:
a setup unit configured to set the operation mode in response to signals that are inputted through all of the plurality of buffers selected before the operation mode is set.

6. The integrated circuit chip of claim 1, wherein the integrated circuit chip is configured to operate in different speeds according to the operation mode.

7. The integrated circuit chip of claim 1, wherein the second buffers are inverter-type buffers, and the first buffers are amplifier-type buffers.

8. The integrated circuit chip of claim 1, further comprising:
a plurality of selectors configured to select outputs of the first buffers or output of the second buffers according to the operation mode.

9. A system, comprising:
a master chip;
a slave chip comprising a plurality of first buffers and a plurality of second buffers, wherein the plurality of first buffers are configured to receive signals of a higher frequency than the plurality of second buffers; and
a plurality of lines configured to transfer signals between the master chip and the slave chip,
wherein the master chip is configured to set an operation mode of the slave chip, and the slave chip is configured to select one group between the plurality of first buffers and the plurality of second buffers and receive the signals of the lines by using the selected buffers according to the set operation mode.

10. The system of claim 9, wherein the system is configured to be set in the operation mode during an initial operation of the slave chip.

11. The system of claim 9, wherein one group between the plurality of first buffers and the plurality of second buffers selectively output the signal input to the selected buffers before the operation mode is set.

12. The system of claim 11, wherein the slave chip further comprises:
a setup unit configured to set the operation mode in response to signals that are inputted through a portion of the plurality of buffers selected before the operation mode is set.

13. The system of claim 11, wherein the slave chip further comprises:
a setup unit configured to set the operation mode in response to signals that are inputted through all of the plurality of buffers selected before the operation mode is set.

14. The system of claim 9, wherein the system receives the signals that are transferred through the lines of a frequency that is different according to the set operation mode.

15. A method for operating a system including a master chip and a slave chip, comprising:
setting an operation mode of the slave chip by the master chip;
outputting a signal input to selected buffers that are selected between a plurality of first buffers and a plurality of second buffers in the slave chip in response to the operation mode;
transferring a plurality of signals from the master chip to the slave chip; and
receiving the signals in the slave chip by using the buffers selected in response to the operation mode,
wherein the plurality of first buffers receive signals of a higher frequency than the plurality of second buffers.

16. The method of claim 15, wherein one group of buffers between the first buffers and the second buffers selectively outputs the signals input to the selected buffers before the setting up of the operation mode, and
the operation mode is set in response to the signal inputted through a portion of the buffers selected before the operation mode is set.

17. The method of claim 15, wherein one group of buffers between the first buffers and the second buffers selectively outputs the signals input to the selected buffers before the setting up of the operation mode, and
the operation mode is set in response to the signal inputted through all of the buffers selected before the operation mode is set.

18. The method of claim 15, wherein a frequency of the signals transferred between the master chip and the slave chip is different according to the set operation mode.
